(19) United States
(12) Patent Application Publication
(10) Pub. No.: US 2015/0230340 A1
(43) Pub. Date: Aug. 13, 2015

(54) EMBEDDED BOARD AND METHOD OF MANUFACTURING THE SAME

(71) Applicant: SAMSUNG ELECTRO-MECHANICS CO., LTD., Suwon-Si (KR)

(72) Inventors: Young Mi LEE, Suwon-Si (KR); Jae Soo Lee, Suwon-Si (KR)

(73) Assignee: SAMSUNG ELECTRO-MECHANICS CO., LTD., Suwon-Si (KR)

(21) Appl. No.: 14/488,212

(22) Filed: Sep. 16, 2014

(30) Foreign Application Priority Data
Feb. 10, 2014 (KR) 10-2014-0015091

(51) Int. Cl. H05K 1/18; H05K 1/02; H05K 3/42; H05K 1/11; H05K 3/46; H05K 3/30

(52) U.S. Cl. CPC H05K 1/186; H05K 3/4644; H05K 3/306; H05K 3/429; H05K 1/115; H05K 1/0298

(57) ABSTRACT

There is provided an embedded board and a method of manufacturing the same. According to an exemplary embodiment of the present disclosure, an embedded board includes: an insulating layer made of a photosensitive material; a first circuit pattern formed inside the insulating layer and formed to make a lower surface be exposed from a lower surface of the insulating layer; an electronic device disposed on the first circuit pattern; a second circuit pattern formed on the insulating layer; and a first via formed inside the insulating layer and having an upper surface connected to the second circuit pattern and formed to make a lower surface be exposed from the lower surface of the insulating layer.

### CROSS-REFERENCE TO RELATED APPLICATION

This application claims the foreign priority benefit of Korean Patent Application No. 10-2014-0015091, filed on Feb. 10, 2014, entitled “Embedded Board And Method Of Manufacturing The Same” which is hereby incorporated by reference in its entirety into this application.

### BACKGROUND

Embodiments of the present invention relate to an embedded board and a method of manufacturing the same.

With the increased demand for multi-functional, small and thin cellular phones and electronic devices of information technology (IT), a technology of embedding electronic components, such as ICs, semiconductor chips, active devices and passive devices, into a substrate so as to meet technological demands has been required. Recently, technologies of embedding components into the substrate by various methods have been developed.

According to the general component embedded board, a cavity is formed into an insulating layer of the board and electronic components, such as various devices, ICs, and semiconductor chips, are embedded into the cavity. Next, an adhesive resin, such as prepreg, is applied inside the cavity and on an insulating layer into which the electronic components are embedded. As described above, the electronic components are fixed and the insulating layer is formed, by applying the adhesive resin(See U.S. Pat. No. 7,886,433).

### SUMMARY

An aspect of the present disclosure may provide an embedded board and a method of manufacturing the same capable of improving electrical characteristics.

Another aspect of the present disclosure may provide an embedded board and a method of manufacturing the same capable of controlling a thickness.

Still another aspect of the present disclosure may provide an embedded board and a method of manufacturing the same capable of implementing a high density circuit.

According to an aspect of the present disclosure, an embedded board may include: an insulating layer made of a photosensitive material; a first circuit pattern formed inside the insulating layer and formed to make a lower surface be exposed from a lower surface of the insulating layer; an electronic device disposed on the first circuit pattern; a second circuit pattern formed on the insulating layer; and a first via formed inside the insulating layer and having an upper surface connected to the second circuit pattern and formed to make a lower surface be exposed from the lower surface of the insulating layer.

The second circuit pattern may be formed on the upper surface of the insulating layer and may thus be formed to protrude from the insulating layer.

The second circuit pattern may be formed inside the insulating layer and may be formed to make an upper surface be exposed from the upper surface of the insulating layer.

The embedded substrate may further include: a second via formed inside the insulating layer, formed to make an upper surface be exposed from the upper surface of the insulating layer, and having a lower surface electrically connected to the electronic device.

The insulating layer may include: a first insulating layer provided with the first circuit pattern; and a second insulating layer provided with the second circuit pattern.

The first insulating layer may have a thickness larger than a sum of thicknesses of the electronic device and the first circuit pattern.

The electronic device may be electrically connected to the first circuit pattern.

The embedded substrate may further include: a solder resist layer formed on at least one of the upper and lower portions of the insulating layer.

The solder resist layer may be made of the photosensitive material.

The first via may be electrically connected to a side of the first circuit pattern.

According to another aspect of the present disclosure, a method of manufacturing an embedded board may include: preparing a carrier member provided with a first circuit pattern; forming a first insulating layer made of a photosensitive material in the carrier member so as to have the first circuit pattern embedded therein; forming a cavity through which the first circuit pattern is exposed by exposing and developing the first insulating layer; disposing an electronic device in the first circuit pattern exposed through the cavity; forming a second insulating layer made of the photosensitive material on the first insulating layer and inside the cavity; and forming a second circuit pattern in a first via penetrating through the first insulating layer and the second insulating layer.

The method may further include: after the forming of the second circuit pattern, removing the carrier member.

The method may further include: after the disposing of the electronic device, performing a reflow by interposing a solder between the electronic device and the first circuit pattern.

The forming of the first via and the second circuit pattern may include: forming a first via hole penetrating through the first insulating layer and the second insulating layer by performing exposure and development; and forming the first via and the second circuit pattern over the first via hole and the second insulating layer by performing plating.

The forming of the first via and the second circuit pattern may include: forming a second via formed in the first insulating layer and the second insulating layer so as to be electrically connected to the electronic device.

The forming of the first via, the second circuit pattern, and the second via may include: forming a first via hole penetrating through the first insulating layer by performing exposure and development; forming an opening in the second insulating layer by performing exposure and development and forming a second via hole through which an upper surface of the electronic device is exposed; and forming the first via, the second circuit pattern, and the second via by performing the plating on the first via hole, the opening, and the second via hole.

The method may further include: after the removing of the carrier member, forming a solder resist layer beneath the first insulating layer and on the second insulating layer.

In the forming of the first insulating layer, the first insulating layer may have a thickness larger than a sum of thicknesses of the electronic device and the first circuit pattern.

The forming of the cavity may include forming an internal via hole by exposing and developing the first insulating layer.

In the forming of the second insulating layer, the second insulating layer may be filled inside the internal via hole.

In the forming of the first via and the second circuit pattern, the first via may be formed in the internal via hole filled with the second insulating layer.

In the forming of the first via and the second circuit pattern, the first via may be electrically connected to a side of the second circuit pattern.

In the forming of the solder resist layer, the solder resist layer may be made of the photosensitive material.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an exemplified view illustrating an embedded board according to a first exemplary embodiment of the present disclosure;

FIGS. 2 through 12 are exemplified views illustrating a method of manufacturing the embedded board according to the first exemplary embodiment of the present disclosure;

FIG. 13 is an exemplified view illustrating an embedded board according to a second exemplary embodiment of the present disclosure; and

FIGS. 14 through 24 are exemplified views illustrating a method of manufacturing the embedded board according to the second exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

### First Exemplary Embodiment

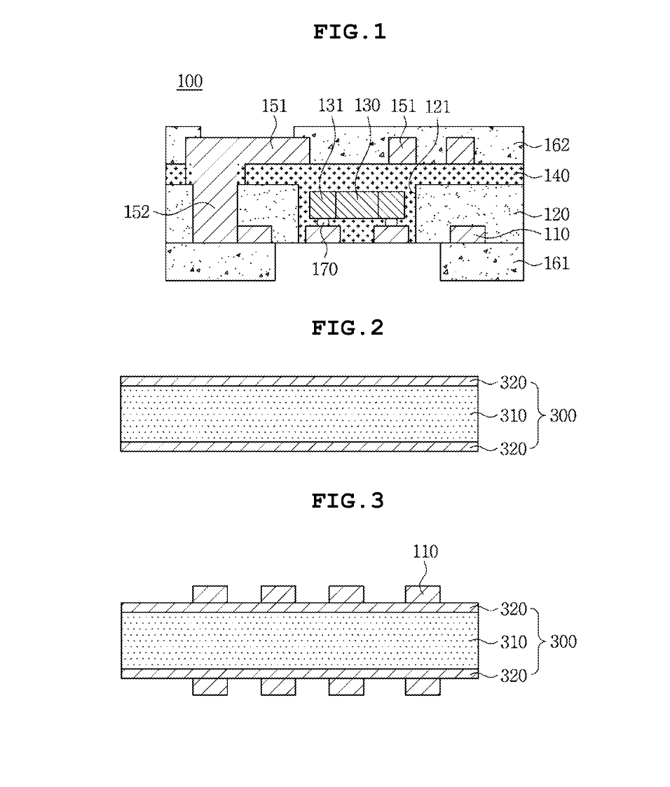

FIG. 1 is an exemplified view illustrating an embedded board according to a first exemplary embodiment of the present disclosure.

Referring to FIG. 1, an embedded board 100 may include a first insulating layer 120, a second insulating layer 140, a first circuit pattern 110, an electronic device 130, a second circuit pattern 151, a via 152, a first solder resist layer 161, and a second solder resist layer 162.

According to the exemplary embodiment of the present disclosure, the first insulating layer 120 and the second insulating layer 140 may be made of a photosensitive material among insulating materials which are used for interlayer insulation in a circuit board field. For example, the first insulating layer 120 and the second insulating layer 140 may be made of a positive type photosensitive insulating material. In the case of the positive type photosensitive insulating material, photopolymer coupling of a light receiving portion may be broken during an exposure process. Next, when a developing process is performed, the portion at which the photopolymer coupling is broken may be removed. Further, the first insulating layer 120 and the second insulating layer 140 may be made of a negative type photosensitive insulating material. The negative type photosensitive insulating material may be cured by forming a three-dimensional mesh structure such as a chain structure in a single structure by causing photo-polymerization reaction at a light receiving portion during an exposure process. Next, when a developing process is performed, a non-cured portion may be removed. The first insulating layer 120 and the second insulating layer 140 may also be made of the same type of photosensitive insulating material and may be made of different types of photosensitive insulating materials.

According to the exemplary embodiment of the present disclosure, the second insulating layer 140 may be formed on the first insulating layer 120. According to the exemplary embodiment of the present disclosure, the first insulating layer 120 and the second insulating layer 140 may be formed to have different thicknesses. In this configuration, the first insulating layer 120 may be formed to have a thickness larger than that of the electronic device 130. Therefore, the entire thickness of the embedded board 100 may be controlled by controlling the thickness of the second insulating layer 140. For example, as the thickness of the second insulating layer 140 is reduced, the thickness of the embedded board 100 may also be reduced.

According to the exemplary embodiment of the present disclosure, the first circuit pattern 110 may be formed to be embedded inside the first insulating layer 120. In this case, a lower surface of the first circuit pattern 110 may be formed to be exposed from a lower surface of the first insulating layer 120. The first circuit pattern 110 may be made of a conductive material. For example, the first circuit pattern 110 may be made of copper. However, the material of the first circuit pattern is not limited to copper. That is, any conductive material used in a circuit board field may be applied to the first circuit layer 110 without being limited.

According to the exemplary embodiment of the present disclosure, the electronic device 130 may be disposed over the first circuit pattern 110. For example, the electronic device 130 may be a multi layer ceramic capacitor (MLCC) having electrodes 131 formed at both sides thereof. However, the electronic device 130 is not limited to the MLCC, but may be any type of devices which may be mounted on the circuit board. The electronic device 130 is disposed over the first circuit pattern 110 to be electrically connected to the first circuit pattern 110. That is, the electrode 131 of the electronic device 130 may be bonded to the first circuit pattern 110 by a solder 170. As such, the electronic device 130 is directly electrically connected to the first circuit pattern 110 and thus a signal transmission distance between the electronic device 130 and the first circuit pattern 110 is shortened, such that electrical characteristics may be improved.

According to the exemplary embodiment of the present disclosure, the second circuit pattern 151 may be formed in the second insulating layer 140 to protrude from the first insulating layer 120. The second circuit pattern 151 may be made of a conductive material. For example, the second circuit pattern 151 may be made of copper. However, the material of the second circuit pattern is not limited to copper. That is, any conductive material used in the circuit board field may be applied to the second circuit layer 151 without being limited.

According to the exemplary embodiment of the present disclosure, the via 152 may be formed to penetrate through the first insulating layer 120 and the second insulating layer 140. A lower surface of the via 152 may be formed to protrude from the lower surface of the first insulating layer 120. Further, an upper surface of the via 152 may be bonded to the second circuit pattern 151 to be electrically connected to the second circuit pattern 151.

The via 152 according to the exemplary embodiment of the present disclosure has a landless structure, and therefore a separate via land is not formed under the via 152. Therefore, a space corresponding to a size of the via land of the related art may be used. That is, the via land is omitted, and thus a freedom of design may be increased and a high-density circuit may be implemented.

According to the exemplary embodiment of the present disclosure, the first solder resist layer 161 may be formed beneath the first insulating layer 120. Further, the first solder resist layer 161 is formed to enclose the lower surface of the first circuit pattern 110 and the lower surface of the via 152 which are exposed from the first insulating layer 120 and thus may be protected from the outside. In this case, the first solder resist layer 161 may be formed to make a portion electrically connected to the outside in the via 152 and the first circuit pattern 110 be exposed to the outside.

According to the exemplary embodiment of the present disclosure, the second solder resist layer 162 may be formed on the second insulating layer 140. The second solder resist layer 162 may be formed to surround the second circuit pattern 151 formed on the second insulating layer 140 and thus may be protected from the outside. In this case, the second solder resist layer 162 may be formed to make a portion electrically connected to the outside in the second circuit pattern 151 be exposed to the outside. For example, the first solder resist layer 161 and the second solder resist layer 162 may be made of a heat resistant covering material.

According to the exemplary embodiment of the present disclosure, the first solder resist layer 161 and the second solder resist layer 162 may be made of the photosensitive material. When the first solder resist layer 161 and the second solder resist layer 162 are made of the photosensitive material, a difference in coefficient of thermal expansion (C 1E) between the first insulating layer 120 and the second insulating layer 140 may be reduced. For example, the first solder resist layer 161, the second solder resist layer 162, the first insulating layer 120, and the second insulating layer 140 may have the same CTE. The so formed embedded board 10 is advantageous in warpage property prediction and therefore may be manufactured to improve the warpage or to be warped according to a customer's demand.

Although not illustrated in the exemplary embodiment of the present disclosure, an area exposed by the first solder resist layer 161 and the second solder resist layer 162 may be subjected to surface treatment.

FIGS. 2 through 12 are exemplified views illustrating a method of manufacturing the embedded board according to the first exemplary embodiment of the present disclosure.

Referring to FIG. 2, a carrier member 300 may be provided.

According to the exemplary embodiment of the present disclosure, when the circuit pattern, the insulating layer, and the like are formed, the carrier member 300 is to support the circuit pattern, the insulating layer, and the like. The carrier member 300 may be made of an insulating material or a metal material. According to the exemplary embodiment of the present disclosure, the carrier member 300 has a copper-clad laminate plate structure in which both surfaces of the carrier insulating layer 310 are provided with carrier metal layers 320. However, the material and the structure of the carrier member 300 are not limited thereto, but any material and structure of the carrier member used in the circuit board field may also be applied.

According to the exemplary embodiment of the present disclosure, the carrier metal layer 320 may be made of copper. However, the material of the carrier metal layer 320 is not limited to copper.

Referring to FIG. 3, the carrier member 300 may be provided with the first circuit pattern 110.

According to the exemplary embodiment of the present disclosure, the first circuit pattern 110 may be formed on the carrier metal layer 320. A process of forming the first circuit pattern 110 may be selected from processes of forming a circuit pattern used in the circuit board field, such as a tenting process, a semi-additive process (SAP), and a modify semi-additive process (MSAP). Further, the first circuit pattern 110 may be made of a conductive material. For example, the first circuit pattern 110 may be made of copper. However, the material of the first circuit pattern is not limited to copper. That is, any conductive material used in a circuit board field may be applied to the first circuit layer 110 without being limited.

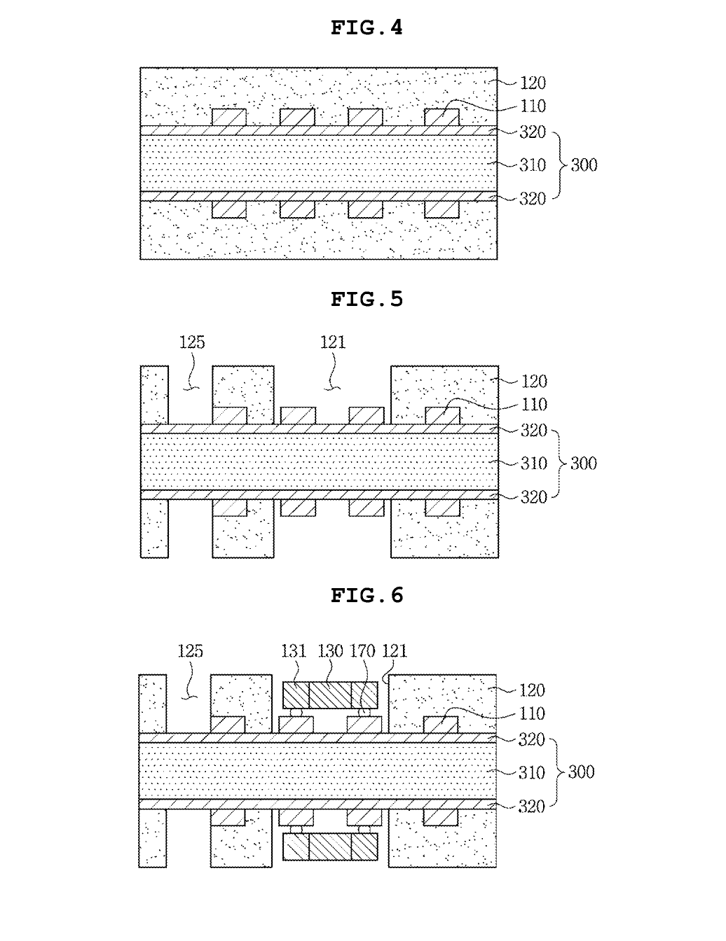

Referring to FIG. 4, the first insulating layer 120 may be formed.

According to the exemplary embodiment of the present disclosure, the first insulating layer 120 may be formed in the carrier member 300. For example, the first insulating layer 120 is laminated on the carrier metal layer 320 in a film type and then is pressed and heated, and as a result, the first insulating layer 120 may be formed to embed the first circuit pattern 110. Alternatively, the first insulating layer 120 may be formed by being applied on the carrier metal layer 320 and the first circuit pattern 110 in a liquid type.

The first insulating layer 120 according to the exemplary embodiment of the present disclosure may be made of the photosensitive material among the insulating materials used for interlayer insulation. For example, the first insulating layer 120 may be made of the positive type photosensitive insulating material or the negative type photosensitive insulating material.

According to the exemplary embodiment of the present disclosure, the first insulating layer 120 may be formed on the carrier metal layer 320 and as a result may be formed to embed the first circuit pattern 110. Further, the first insulating layer 120 may be formed to have a thickness which is larger than a sum of the thicknesses of the electronic device (not illustrated) and the first circuit pattern 110 which are disposed inside the first insulating layer 120.

Referring to FIG. 5, a cavity 121 and an internal via hole 125 may be formed in the first insulating layer 120.

According to the exemplary embodiment of the present disclosure, the cavity 121 and the internal via hole 125 may be formed by performing the exposure and developing processes on the first insulating layer 120. For example, when the first insulating layer 120 is the positive type, the exposure process may be performed on an area of the first insulating layer 120 in which the cavity 121 is formed. Next, the developing process is performed to remove the exposed area from the first insulating layer 120 and thus the cavity 121 may be formed. Alternatively, when the first insulating layer 120 is the negative type, the exposure process may be performed, excepting the area of the first insulating layer 120 in which the cavity 121 is formed. Next, the developing process is performed to remove the non-exposed area from the first insulating layer 120 and thus the cavity 121 may be formed.

In this case, the cavity 121 may be formed to expose the first circuit pattern 110 in which the electronic device (not illustrated) is mounted later.

According to the exemplary embodiment of the present disclosure, the internal via hole 125 may be simultaneously formed with the cavity 121. The internal via hole 125 may be formed to completely penetrate through the first insulating layer 120. Further, the internal via hole 125 may be formed to expose a side of the first circuit pattern 110.

Referring to FIG. 6, the electronic device 130 may be disposed.

According to the exemplary embodiment of the present disclosure, the electronic device 130 may be disposed in the cavity 121 of the first insulating layer 120. For example, the electronic device 130 may be the MLCC having the electrodes 131 formed at both sides thereof. However, the electronic device 130 is not limited to the MLCC, but may be any type of devices which may be mounted on the circuit board.

The electronic device 130 may be disposed over the first circuit pattern 110 which is exposed through the cavity 121. In this case, the solder may be interposed between the electrode 131 of the electronic device 130 and the first circuit pattern 110. Next, a reflow may be performed to bond the electronic device 130 to the first circuit pattern 110. In this case, the electrode 131 of the electronic device 130 may be electrically connected to the first circuit pattern 110. As such, the electronic device 130 is directly electrically connected to the first circuit pattern 110 and thus a signal transmission distance between the electronic device 130 and the first circuit pattern 110 is shortened, such that electrical characteristics may be improved.

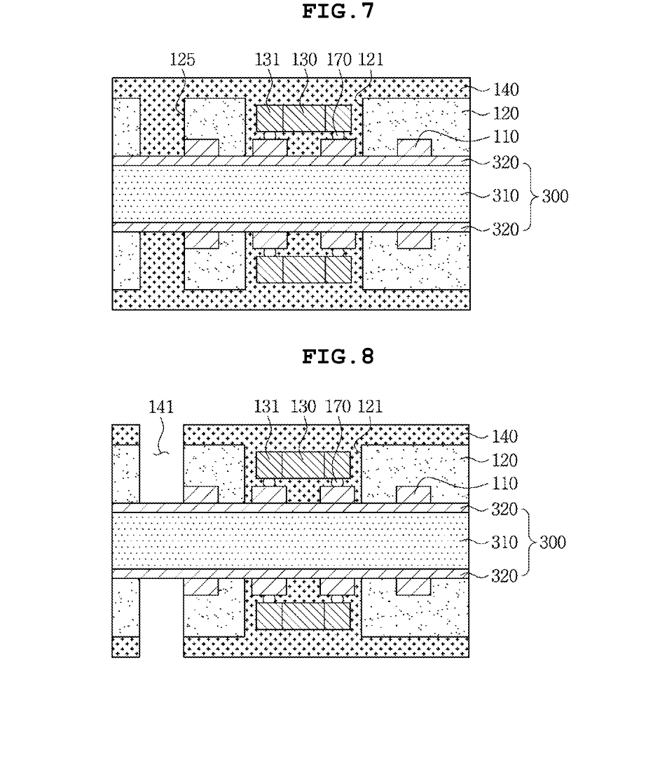

Referring to FIG. 7, the second insulating layer 140 may be formed.

According to the exemplary embodiment of the present disclosure, the second insulating layer 140 may be formed on the first insulating layer 120. Further, the second insulating layer 140 may be formed to fill the cavity 121 of the first insulating layer 120 in which the electronic device 130 is disposed. Further, the second insulating layer 140 may be formed to fill the internal via hole 125 of the first insulating layer 120. For example, the second insulating layer 140 is laminated on the first insulating layer 120 in the film type and then is pressed and heated, and as a result, may fill the cavity 121 and the internal via hole 125 of the first insulating layer 120. Alternatively, the second insulating layer 140 may be formed by being applied on the first insulating layer 120 and to the cavity and the internal via hole 125 in the liquid type.

The second insulating layer 140 according to the exemplary embodiment of the present disclosure may be made of the photosensitive material among the insulating materials used for interlayer insulation in the circuit board field. For example, the second insulating layer 140 may be made of the positive type photosensitive insulating material or the negative type photosensitive insulating material.

According to the exemplary embodiment of the present disclosure, since the first insulating layer 120 is formed to have a thickness which is larger than the sum of thicknesses of the electronic device 130 and the first circuit pattern 110, the thickness of the second insulating layer 140 may be controlled to control the entire thickness of the embedded board 100 (FIG. 1). For example, as the thickness of the second insulating layer 140 is reduced, the thickness of the embedded board 100 (FIG. 1) may also be reduced.

Referring to FIG. 8, a via hole 141 may be formed.

According to the exemplary embodiment of the present disclosure, the via hole 141 may be formed to penetrate through the first insulating layer 120 and the second insulating layer 140. The via hole 141 according to the exemplary embodiment of the present disclosure may be formed by performing the exposure and developing processes. For example, when the first insulating layer 120 and the second insulating layer 140 are the positive type, the area in which the via hole 141 is formed may be subjected to the exposure process. Next, the developing process is performed to remove the exposed area from the first insulating layer 120 and the second insulating layer 140 and thus the via hole 141 may be formed. Alternatively, when the first insulating layer 120 and the second insulating layer 140 are the negative type, the exposure process may be performed, excepting the area in which the via hole 141 is formed. Next, the developing process is performed to remove the non-exposed area from the first insulating layer 120 and the second insulating layer 140 and thus the via hole 141 may be formed.

According to the exemplary embodiment of the present disclosure, the via hole 141 may be formed in the area in which the internal via hole 125 (FIG. 6) is formed. Therefore, the via hole 141 may be formed to expose the side of the first circuit pattern 110. For example, even though the internal via hole 125 (FIG. 6) is not formed to expose the side of the first circuit pattern 110, the via hole 141 may be formed to expose the side of the first circuit pattern 110.

Further, the exemplary embodiment of the present disclosure describes, by way of example, that both of the internal via hole 125 (FIG. 6) and the via hole 141 are formed, but is not limited thereto. According to the selection of those skilled in the art, the process of forming the internal via hole 125 (FIG. 6) may be omitted.

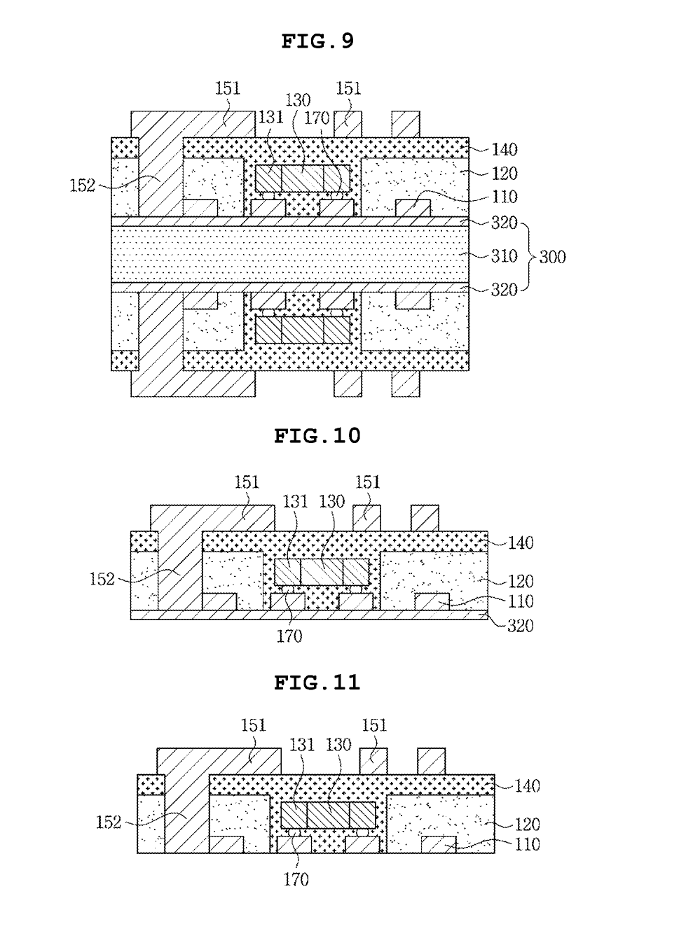

Referring to FIG. 9, the via 152 and the second circuit pattern 151 may be formed.

According to the exemplary embodiment of the present disclosure, the via 152 may be formed by filling the conductive material in the via hole 141. In this case, the via 152 may contact the side of the first circuit pattern 110 which is exposed through the via hole 141. Therefore, the via 152 may be formed to be electrically connected to the first circuit pattern 110 through the side of the first circuit pattern 110.

According to the exemplary embodiment of the present disclosure, the conductive material forming the via 152 may be made of any one of conductive paste, conductive ink, and conductive metal. Here, when the via 152 is made of the conductive paste, the via 152 may be formed by a screen printing process. Alternatively, when the via 152 is made of the conductive ink, the via 152 may be formed by an inkjet. Alternatively, when the via 152 is made of the conductive metal, the via 152 may be formed by the SAP or the MSAP.

According to the exemplary embodiment of the present disclosure, the second circuit pattern 151 may be formed on the second insulating layer 140. The second circuit pattern 151 may be formed on the second insulating layer 140 and thus may be formed in a protruding structure from the second insulating layer 140. The second circuit pattern 151 according to the exemplary embodiment of the present disclosure may be made of the conductive material. For example, the second circuit pattern 151 may be made of copper. However, the material of the second circuit pattern is not limited to copper. That is, any conductive material used in the circuit board field may be applied to the second circuit layer 151 without being limited. Further, the second circuit pattern 151 may be formed by the process of forming a circuit pattern used in the circuit board field, such as the tenting process, the semi-additive process (SAP), and the modify semi-additive process (MSAP).

According to the exemplary embodiment of the present disclosure, the via 152 and the second circuit pattern 151 may be simultaneously formed by the same process and material. However, according to the selection of those skilled in the art, the process and material for forming the via 152 and the second circuit pattern 151 may be changed.

According to the exemplary embodiment of the present disclosure, the via hole 141 may be formed to penetrate through the first insulating layer 120 and the second insulating layer 140. Therefore, the via 152 formed in the via hole 141 may also be formed to penetrate through the first insulating layer 120 and the second insulating layer 140. Therefore, the lower surface of the via 152 may be formed to protrude from the lower surface of the first insulating layer 120. Further, according to the exemplary embodiment of the present disclosure, the upper surface of the via 152 may be bonded to the second circuit pattern 151. Therefore, the via 152 may be electrically connected to the second circuit pattern 151.

Referring to FIG. 10, a carrier insulating layer 310 (FIG. 9) may be removed.

According to the exemplary embodiment of the present disclosure, a carrier metal layer 320 may be separated from the carrier insulating layer 310 (FIG. 9). In this case, only the carrier insulating layer 310 (FIG. 9) is separated and the carrier metal layer 320 may remain under the first insulating layer 120, the via 152, and the first circuit pattern 110.

Referring to FIG. 11, the carrier metal layer 320 (FIG. 10) may be removed.

According to the exemplary embodiment of the present disclosure, the carrier metal layer 320 (FIG. 10) is removed and thus the lower surface of the first insulating layer 120, the lower surface of the via 152, and the lower surface of the first circuit pattern 110 may be exposed to the outside.

The exemplary embodiment of the present disclosure describes, by way of example, that when the carrier member 300 (FIG. 9) is removed, the carrier insulating layer 310 (FIG. 9) and the carrier metal layer 320 (FIG. 9) are removed separately. However, a method of removing the carrier member 300 (FIG. 9) is not limited thereto. The carrier member 300 (FIG. 9) may be removed by various methods according to the structure, the material, and the selection of those skilled in the art.

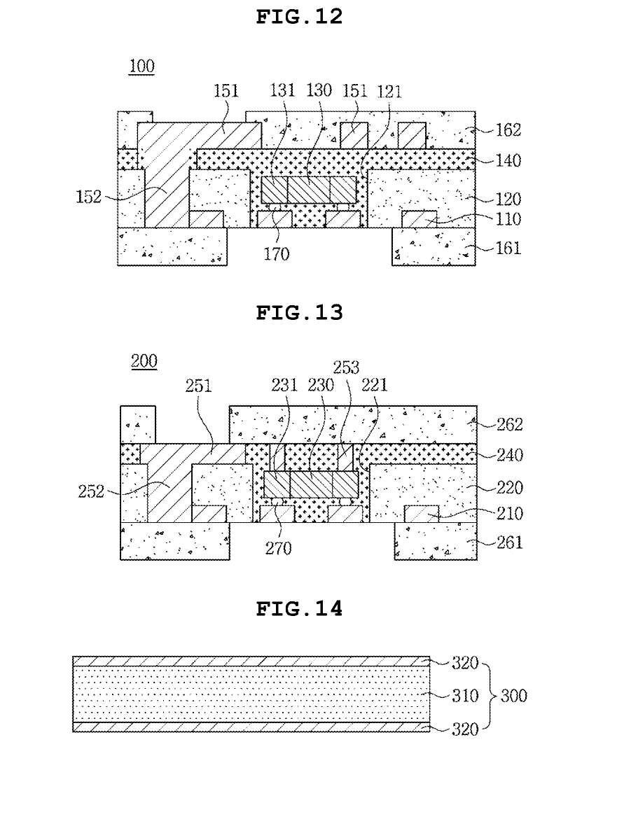

Referring to FIG. 12, the first solder resist layer 161 and the second solder resist layer 162 may be formed.

According to the exemplary embodiment of the present disclosure, the first solder resist layer 161 may be formed beneath the first insulating layer 120. Further, the first solder resist layer 161 is formed to enclose the lower surface of the first circuit pattern 110 and the lower surface of the via 152 which are exposed from the first insulating layer 120. In this case, the first solder resist layer 161 may be formed to make a portion electrically connected to the outside in the via 152 and the first circuit pattern 110 be exposed to the outside.

According to the exemplary embodiment of the present disclosure, the second solder resist layer 162 may be formed on the second insulating layer 140. The second solder resist layer 162 may be formed to surround the second circuit pattern 151 formed on the second insulating layer 140. In this case, the second solder resist layer 162 may be formed to make a portion electrically connected to the outside in the second circuit pattern 151 be exposed to the outside. For example, the first solder resist layer 161 and the second solder resist layer 162 may be made of a heat resistant covering material.

According to the exemplary embodiment of the present disclosure, the first solder resist layer 161 and the second solder resist layer 162 may be made of the photosensitive material. When the first solder resist layer 161 and the second solder resist layer 162 are made of the photosensitive material, a difference in coefficient of thermal expansion (C 1′E) between the first insulating layer 120 and the second insulating layer 140 may be reduced. For example, the first solder resist layer 161, the second solder resist layer 162, the first insulating layer 120, and the second insulating layer 140 may have the same CTE. The so formed embedded board 10 is advantageous in warpage property prediction and therefore may be manufactured to improve the warpage or to be warped according to a customer's demand.

Although not illustrated in the exemplary embodiment of the present disclosure, an area exposed by the first solder resist layer 161 and the second solder resist layer 162 may be subjected to surface treatment.

According to the related art, when the via hole is process by a laser drill which is a physical scheme, due to the presence of the via land, it is possible to prevent the insulating material disposed under the via land from being processed. However, according to the exemplary embodiment of the present disclosure, when the first insulating layer and the second insulating layer are made of the photosensitive insulating material, the via hole may be formed by the exposure and developing processes which are a chemical scheme. Therefore, according to the exemplary embodiment of the present disclosure, the via hole may be processed regardless of the absence and presence of the via land. As described above, according to the exemplary embodiment of the present disclosure, the via land is omitted and thus the freedom of circuit design may be improved.

### Second Exemplary Embodiment

FIG. 13 is an exemplified view illustrating an embedded board according to a second exemplary embodiment of the present disclosure.

Referring to FIG. 13, an embedded board 200 may include a first insulating layer 220, a second insulating layer 240, a first circuit pattern 210, an electronic device 230, a second circuit pattern 251, a first via 252, a second via 253, a first solder resist layer 261, and a second solder resist layer 262.

According to the exemplary embodiment of the present disclosure, the first insulating layer 220 and the second insulating layer 240 may be made of a photosensitive material among insulating materials which are used for interlayer insulation in a circuit board field. For example, the first insulating layer 220 and the second insulating layer 240 may be made of a positive type photosensitive insulating material. In the case of the positive type photosensitive insulating material, photopolymer coupling of a light receiving portion may be broken during an exposure process. Next, when a developing process is performed, the portion at which the photopolymer coupling is broken may be removed. Further, the first insulating layer 220 and the second insulating layer 240 may be made of a negative type photosensitive insulating material. The negative type photosensitive insulating material may be cured by forming a three-dimensional mesh structure such as a chain structure in a single structure by causing photo-polymerization reaction at a light receiving portion during an exposure process. Next, when a developing process is performed, a non-cured portion may be removed. The first insulating layer 220 and the second insulating layer 240 may also be made of the same type of photosensitive insulating material and may be made of different types of photosensitive insulating materials.

According to the exemplary embodiment of the present disclosure, the second insulating layer 240 may be formed on the first insulating layer 220. According to the exemplary embodiment of the present disclosure, the first insulating layer 220 and the second insulating layer 240 may be formed to have different thicknesses. In this configuration, the first insulating layer 220 may be formed to have a thickness larger than that of the electronic device 230. For example, the first insulating layer 220 may be formed to have the thickness which is larger than the sum of the thicknesses of the electronic device 230 and the first circuit pattern 210 so as to embed the electronic device 230. Therefore, the entire thickness of the embedded board 200 may be controlled by controlling the thickness of the second insulating layer 240. For example, as the thickness of the second insulating layer 240 is reduced, the thickness of the embedded board 200 may also be reduced.

According to the exemplary embodiment of the present disclosure, the first circuit pattern 210 may be formed to be embedded inside the first insulating layer 220. In this case, a lower surface of the first circuit pattern 210 may be formed to be exposed from a lower surface of the first insulating layer 220. The first circuit pattern 210 may be made of a conductive material. For example, the first circuit pattern 210 may be made of copper. However, the material of the first circuit pattern is not limited to copper. That is, any conductive material used in a circuit board field may be applied to the first circuit layer 210 without being limited.

According to the exemplary embodiment of the present disclosure, the electronic device 230 may be disposed over the first circuit pattern 210. For example, the electronic device 230 may be the MLCC having the electrodes 231 formed at both sides thereof. However, the electronic device 230 is not limited to the MLCC, but may be any type of devices which may be mounted on the circuit board. The electronic device 230 is disposed over the first circuit pattern 210 to be electrically connected to the first circuit pattern 210. That is, the electrode 230 of the electronic device 231 may be bonded to the first circuit pattern 210 by a solder 270. As such, the electronic device 230 is directly electrically connected to the first circuit pattern 210 and thus a signal transmission distance between the electronic device 230 and the first circuit pattern 210 is shortened, such that electrical characteristics may be improved.

According to the exemplary embodiment of the present disclosure, the second circuit pattern 251 may be formed to be embedded inside the second insulating layer 240. Further, the second circuit pattern 251 may be formed to be exposed from an upper surface of the second insulating layer 240. The second circuit pattern 251 may be made of a conductive material. For example, the second circuit pattern 251 may be made of copper. However, the material of the second circuit pattern is not limited to copper. That is, any conductive material used in the circuit board field may be applied to the second circuit layer 251 without being limited.

According to the exemplary embodiment of the present disclosure, the first via 252 may be formed to penetrate through the first insulating layer 220. A lower surface of the first via 252 may be formed to be exposed from the lower surface of the first insulating layer 220. Further, an upper surface of the first via 252 may be bonded to the second circuit pattern 251 to be electrically connected to the second circuit pattern 151. The first via 252 according to the exemplary embodiment of the present disclosure has a landless structure, and therefore a separate via land is not formed under the via 252. Therefore, a space corresponding to a size of the via land of the related art may be used. That is, the via land is omitted, and thus a freedom of design may be increased and a high-density circuit may be implemented.

According to the exemplary embodiment of the present disclosure, the second via 253 may be formed to penetrate through the second insulating layer 240. Further, the second via 253 may be formed to penetrate through a portion of the first insulating layer 220. The lower surface of the so formed second via 253 may be bonded to the electrode 231 of the electronic device 230. Therefore, the second via 253 may be electrically connected to the electronic device 230.

According to the exemplary embodiment of the present disclosure, the embedded board may have a structure in which the second via 253 is connected to the upper portion of the electronic element 230 and the first circuit pattern 210 is connected to the lower portion thereof.

According to the exemplary embodiment of the present disclosure, the first via 252 and the second via 253 may be electrically connected to at least one of a power layer and a ground layer.

According to the related art, one electrode of the electronic device is connected to one circuit pattern. In this case, when even one electrode is not electrically connected to the circuit pattern, the corresponding board may be defective.

According to the exemplary embodiment of the present disclosure, all the electrodes 231 formed at both sides of the electronic device 230 may be electrically connected to the first circuit pattern 210 and the second circuit pattern 251. Here, the electrode 231 may be electrically connected to the second circuit pattern 251 through the second via 253. For example, even though any one of the electrodes 231 is not electrically connected to the first circuit pattern 210, is electrically connected to the second circuit pattern 251 and thus as in the related art, a defect may be prevented.

Further, according to the exemplary embodiment of the present disclosure, the electrode 231 of the electronic device 230 may be used as the via through which the first circuit pattern 210 is electrically connected to the second circuit pattern 251 and therefore the freedom of design may be improved.

In this case, one of the second via 253 and the first circuit pattern 210 may be connected to the power layer and the other thereof may be connected to the ground layer. In this case, capacity of the power supply and the ground may be increased by the second via 253 connected to the electronic device 230 and the first circuit pattern 210. Therefore, the electrical characteristics of the embedded board 200 may be improved.

According to the exemplary embodiment of the present disclosure, the first solder resist layer 261 may be formed beneath the first insulating layer 220. Further, the first solder resist layer 261 is formed to enclose the lower surface of the first circuit pattern 210 and the lower surface of the first via 252 which are exposed from the first insulating layer 220 and thus may be protected from the outside. In this case, the first solder resist layer 261 may be formed to make a portion electrically connected to the outside in the first via 252 and the first circuit pattern 210 be exposed to the outside.

According to the exemplary embodiment of the present disclosure, the second solder resist layer 262 may be formed on the second insulating layer 240. The second solder resist layer 262 may be formed to surround the upper surface of the second circuit pattern 251 exposed from the upper surface of the second insulating layer 240 and thus may be protected from the outside. In this case, the second solder resist layer 262 may be formed to make a portion electrically connected to the outside in the second circuit pattern 251 be exposed to the outside. For example, the first solder resist layer 261 and the second solder resist layer 262 may be made of a heat resistant covering material.

According to the exemplary embodiment of the present disclosure, the first solder resist layer 261 and the second solder resist layer 262 may be made of the photosensitive material. When the first solder resist layer 261 and the second solder resist layer 262 are made of the photosensitive material, a difference in coefficient of thermal expansion (CTE) between the first insulating layer 220 and the second insulating layer 240 may be reduced. For example, the first solder resist layer 261, the second solder resist layer 262, the first insulating layer 220, and the second insulating layer 240 may have the same CTE. The so formed embedded board 200 is advantageous in warpage property prediction and therefore may be manufactured to improve the warpage or to be warped according to a customer's demand.

Although not illustrated in the exemplary embodiment of the present disclosure, the area exposed by the first solder resist layer 261 and the second solder resist layer 262 may be subjected to the surface treatment.

FIGS. 14 through 24 are exemplified views illustrating a method of manufacturing the embedded board according to the second exemplary embodiment of the present disclosure.

Referring to FIG. 14, the carrier member 300 may be provided.

According to the exemplary embodiment of the present disclosure, when the circuit pattern, the insulating layer, and the like are formed, the carrier member 300 is to support the circuit pattern, the insulating layer, and the like. The carrier member 300 may be made of an insulating material or a metal material. According to the exemplary embodiment of the present disclosure, the carrier member 300 has a copper-clad laminate plate structure in which both surfaces of the carrier insulating layer 310 are provided with carrier metal layers 320. However, the material and the structure of the carrier member 300 are not limited thereto, but any material and structure of the carrier member used in the circuit board field may also be applied.

According to the exemplary embodiment of the present disclosure, the carrier metal layer 320 may be made of copper. However, the material of the carrier metal layer 320 is not limited to copper.

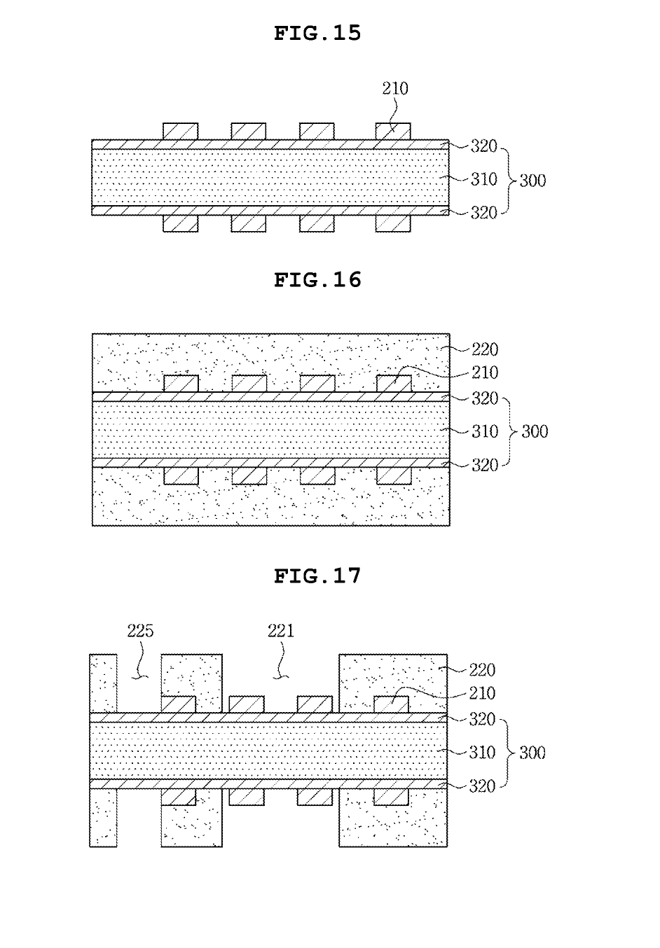

Referring to FIG. 15, the carrier member 300 may be provided with the first circuit pattern 210.

According to the exemplary embodiment of the present disclosure, the first circuit pattern 210 may be formed on the carrier metal layer 320. A process of forming the first circuit pattern 210 may be selected from the processes of forming a circuit pattern used in the circuit board field, such as the tenting process, the semi-additive process (SAP), and the modify semi-additive process (MSAP). Further, the first circuit pattern 210 may be made of a conductive material. For example, the first circuit pattern 210 may be made of copper. However, the material of the first circuit pattern is not limited to copper. That is, any conductive material used in a circuit board field may be applied to the first circuit layer 210 without being limited.

Referring to FIG. 16, the first insulating layer 220 may be formed.

According to the exemplary embodiment of the present disclosure, the first insulating layer 220 may be formed in the carrier member 300. For example, the first insulating layer 220 is laminated on the carrier metal layer 320 in the film type and then is pressed and heated, and as a result, the first insulating layer 120 may be formed to embed the first circuit pattern 210. Alternatively, the first insulating layer 220 may be formed by being applied on the carrier metal layer 320 and the first circuit pattern 110 in the liquid type.

The first insulating layer 220 according to the exemplary embodiment of the present disclosure may be made of the photosensitive material among the insulating materials used for interlayer insulation. For example, the first insulating layer 220 may be made of the positive type photosensitive insulating material or the negative type photosensitive insulating material.

According to the exemplary embodiment of the present disclosure, the first insulating layer 220 may be formed on the carrier metal layer 320 and as a result may be formed to embed the first circuit pattern 210. Further, the first insulating layer 220 may be formed to have a thickness which is larger than a sum of the thicknesses of the electronic device (not illustrated) and the first circuit pattern 210 which are disposed inside the first insulating layer 220.

Referring to FIG. 17, the cavity 221 and the internal via hole 225 may be formed in the first insulating layer 220.

According to the exemplary embodiment of the present disclosure, the cavity 221 and the internal via hole 225 may be formed by performing the exposing and developing processes on the first insulating layer 220. For example, when the first insulating layer 220 is the positive type, the exposure process may be performed on an area of the first insulating layer 220 in which the cavity 221 is formed. Next, the developing process is performed to remove the exposed area from the first insulating layer 220 and thus the cavity 221 may be formed. Alternatively, when the first insulating layer 220 is the negative type, the exposure process may be performed, excepting the area of the first insulating layer 120 in which the cavity 221 is formed. Next, the developing process is performed to remove the non-exposed area from the first insulating layer 220 and thus the cavity 221 may be formed.

In this case, the cavity 221 may be formed to expose the first circuit pattern 110 in which the electronic device (not illustrated) is mounted later.

According to the exemplary embodiment of the present disclosure, the internal via hole 225 may be simultaneously formed with the cavity 221. The internal via hole 225 may be formed to completely penetrate through the first insulating layer 220. Further, the internal via hole 225 may be formed to expose a side of the first circuit pattern 210.

The exemplary embodiment of the present disclosure describes, by way of example, that the internal via hole 225 is formed, but the process of forming the internal via hole 225 may be omitted according to the selection of those skilled in the art.

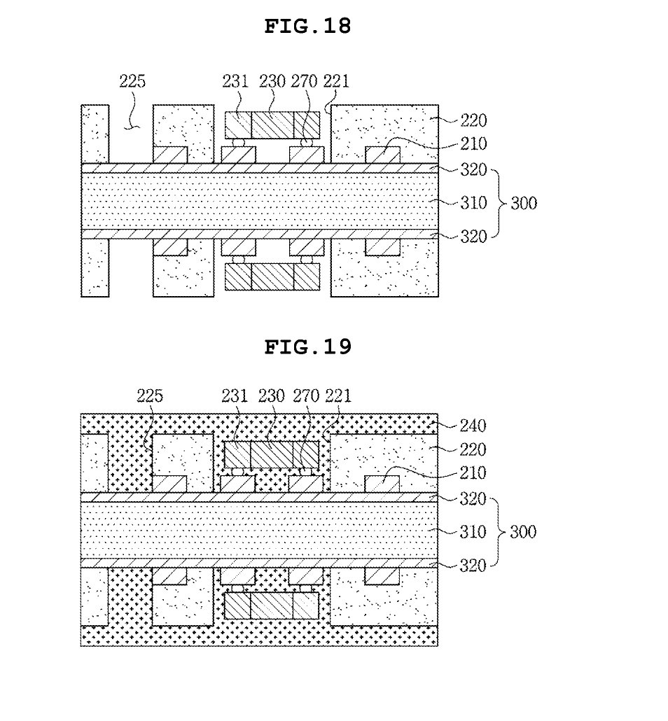

Referring to FIG. 18, the electronic device 230 may be disposed.

According to the exemplary embodiment of the present disclosure, the electronic device 230 may be disposed in the cavity 221 of the first insulating layer 221. For example, the electronic device 230 may be the MLCC having the electrodes 231 formed at both sides thereof. However, the electronic device 230 is not limited to the MLCC, but may be any type of devices which may be mounted on the circuit board.

The electronic device 230 may be disposed over the first circuit pattern 210 which is exposed through the cavity 221. In this case, the solder may be interposed between the electrode 230 of the electronic device 231 and the first circuit pattern 210. Next, a reflow may be performed to bond the electronic device 230 to the first circuit pattern 210. In this case, the electrode 230 of the electronic device 231 may be electrically connected to the first circuit pattern 210. As such, the electronic device 230 is directly electrically connected to the first circuit pattern 210 and thus a signal transmission distance between the electronic device 230 and the first circuit pattern 210 is shortened, such that electrical characteristics may be improved.

Referring to FIG. 19, the second insulating layer 240 may be formed.

According to the exemplary embodiment of the present disclosure, the second insulating layer 240 may be formed on the first insulating layer 220. Further, the second insulating layer 240 may be formed to fill the cavity 221 and the internal via hole 225 of the first insulating layer 220 in which the electronic device 230 is disposed. For example, the second insulating layer 240 is laminated on the first insulating layer 120 in the film type and is then pressed and heated, and as a result, may fill the cavity 221 of the first insulating layer 220. Alternatively, the second insulating layer 240 may be formed by being applied on the first insulating layer 220 and to the cavity 221 and the internal via hole 225 in the liquid type.

The second insulating layer 240 according to the exemplary embodiment of the present disclosure may be made of the photosensitive material among the insulating materials used for interlayer insulation. For example, the second insulating layer 240 may be made of the positive type photosensitive insulating material or the negative type photosensitive insulating material.

According to the exemplary embodiment of the present disclosure, since the first insulating layer 220 is formed to have a thickness which is larger than the sum of thicknesses of the electronic device 230 and the first circuit pattern 210, the thickness of the second insulating layer 240 may be controlled to control the entire thickness of the embedded board 200 (FIG. 1). For example, as the thickness of the second insulating layer 240 is reduced, the thickness of the embedded board 200 (FIG. 13) may also be reduced.

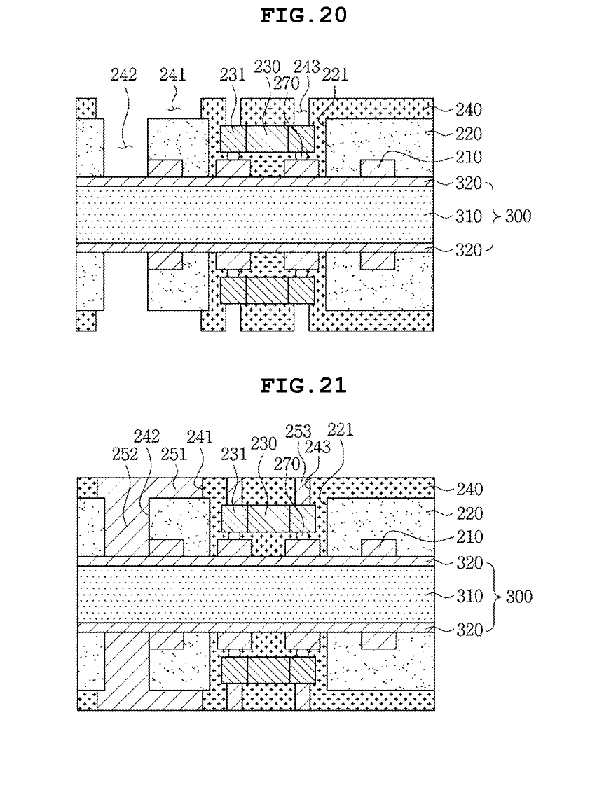

Referring to FIG. 20, the first via hole 242, the second via hole 243, and an opening 241 may be formed.

According to the exemplary embodiment of the present disclosure, the opening 241 may be formed in the area in which the second circuit pattern (not illustrated) is formed.

According to the exemplary embodiment of the present disclosure, the first via hole 1 may be formed in the area in which the internal via hole 125 (FIG. 19) is formed. Here, according to the exemplary embodiment of the present disclosure, the first via hole 242 may be formed in the second insulating layer 240 which is filled in the internal via hole 125 (FIG. 19). When the process of forming the internal via hole 125 (FIG. 19) is omitted, the first via hole 242 may be formed by performing the exposure and developing processes on the first insulating layer 220 exposed through the opening 241. The so formed first via hole 242 may be formed to expose the side of the first circuit pattern 210.

According to the exemplary embodiment of the present disclosure, the second via hole 243 may be formed on the second insulating layer 240 which is formed on the electronic device 230. In this case, the second via hole 243 may be formed to expose the electrode 231 of the electronic device 230.

According to the exemplary embodiment of the present disclosure, all of the opening 241, the first via hole 242, and the second via hole 243 may be formed by the exposure and developing processes.

According to the related art, when the via hole is process by a laser drill which is a physical scheme, due to the presence of the via land, it is possible to prevent the insulating material disposed under the via land from being processed. However, according to the exemplary embodiment of the present disclosure, when the first insulating layer 220 and the second insulating layer 240 are made of the photosensitive insulating material, the first via hole 242 may be formed by the exposure and developing processes which are the chemical scheme. Therefore, according to the exemplary embodiment of the present disclosure, the via hole 242 may be processed regardless of the absence and presence of the via land.

According to the exemplary embodiment of the present disclosure, the exposed portion and the portion removed by development according to the photosensitive type of the first insulating layer 220 and the second insulating layer 240 may be different. That is, the method of forming the first via hole 242, the second via hole 243, and the opening 241 in the type of the first insulating layer 220 and the second insulating layer 240 according to the photosensitive type may be different.

Referring to FIG. 21, the first via 252, the second via 253, and the second circuit pattern 251 may be formed.

According to the exemplary embodiment of the present disclosure, the first via 252 may be formed by filling the conductive material in the first via hole 242. In this case, the first via 252 may contact the side of the first circuit pattern 210 which is exposed through the first via hole 252. Therefore, the first via 252 may be electrically connected to the first circuit pattern 210 through the side of the first circuit pattern 110.

According to the exemplary embodiment of the present disclosure, the first via 252 may be made of any one of the conductive paste, the conductive ink, and the conductive metal. Here, when the first via 252 is made of the conductive paste, the via 152 may be formed by the screen printing process. Alternatively, when the first via 252 is made of the conductive ink, the via 152 may be formed by the inkjet. Alternatively, when the first via 252 is made of the conductive metal, the first via 252 may be formed by the SAP or the MSAP. According to the exemplary embodiment of the present disclosure, the first via hole 242 may be formed to penetrate through the first insulating layer 220. Therefore, the first via 252 formed in the first via hole 242 may also be formed to penetrate through the first insulating layer 220. Further, the lower surface of the first via 252 may be exposed from the lower surface of the first insulating layer 220.

According to the exemplary embodiment of the present disclosure, the second via 253 may be formed by filling the conductive material in the second via hole 243. For example, the second via 253 may be made of any one of the conductive paste, the conductive ink, and the conductive metal. Here, when the second via 253 is made of the conductive paste, the second via 252 may be formed by the screen printing process. Alternatively, when the second via 253 is made of the conductive ink, the second via 252 may be formed by the inkjet. Alternatively, when the second via 253 is made of the conductive metal, the second via 252 may be formed by the SAP or the MSAP.

According to the exemplary embodiment of the present disclosure, the embedded board may have a structure in which the second via 253 is connected to the upper portion of the electronic element 230 and the first circuit pattern 210 is connected to the lower portion thereof. In this case, one of the second via 253 and the first circuit pattern 210 may be connected to the power layer and the other thereof may be connected to the ground layer. In this case, capacity of the power supply and the ground may be increased by the second via 253 connected to the electronic device 230 and the first circuit pattern 210. Therefore, the electrical characteristics of the embedded board 200 may be improved.

According to the exemplary embodiment of the present disclosure, the second circuit pattern 251 may be formed by filling the conductive material in the opening 241 of the second insulating layer 240. Therefore, the second circuit pattern 251 is embedded in the second insulating layer 240 and may be formed to make the upper surface be exposed from the upper surface of the second insulating layer 240. Further, the lower surface of the second circuit pattern 251 may be bonded to the upper surface of the first via 252. Therefore, the first circuit pattern 210 may be electrically connected to the first via 252. The second circuit pattern 251 according to the exemplary embodiment of the present disclosure may be made of the conductive material. For example, the second circuit pattern 251 may be made of copper. However, the material of the second circuit pattern is not limited to copper. That is, any conductive material used in the circuit board field may be applied to the second circuit layer 251 without being limited. Further, the second circuit pattern 251 may be formed by the process of forming a circuit pattern used in the circuit board field, such as the tenting process, the semi-additive process (SAP), and the modify semi-additive process (MSAP).

According to the exemplary embodiment of the present disclosure, the first via 252, the second via 253, and the second circuit pattern 251 may be simultaneously formed by the same process and material. However, according to the selection of those skilled in the art, the process and material for forming the first via 252, the second via 253, and the second circuit pattern 251 may be changed. According to the exemplary embodiment of the present disclosure, the first via 252 and the second via 253 may be electrically connected to at least one of a power layer and a ground layer.

According to the related art, one electrode of the electronic device is connected to one circuit pattern. In this case, when even one electrode is not electrically connected to the circuit pattern, the corresponding board may be defective.

According to the exemplary embodiment of the present disclosure, all the electrodes 231 formed at both sides of the electronic device 230 may be electrically connected to the first circuit pattern 210 and the second circuit pattern 251. Here, the electrode 231 may be electrically connected to the second circuit pattern 251 through the second via 253. For example, even though any one of the electrodes 231 is not electrically connected to the first circuit pattern 210, any one of the electrodes 231 is electrically connected to the second circuit pattern 251 and thus a defect as in the related art may be prevented.

Further, according to the exemplary embodiment of the present disclosure, the electrode 231 of the electronic device 230 may be used as the via through which the first circuit pattern 210 is electrically connected to the second circuit pattern 251 and therefore the freedom of design may be improved.

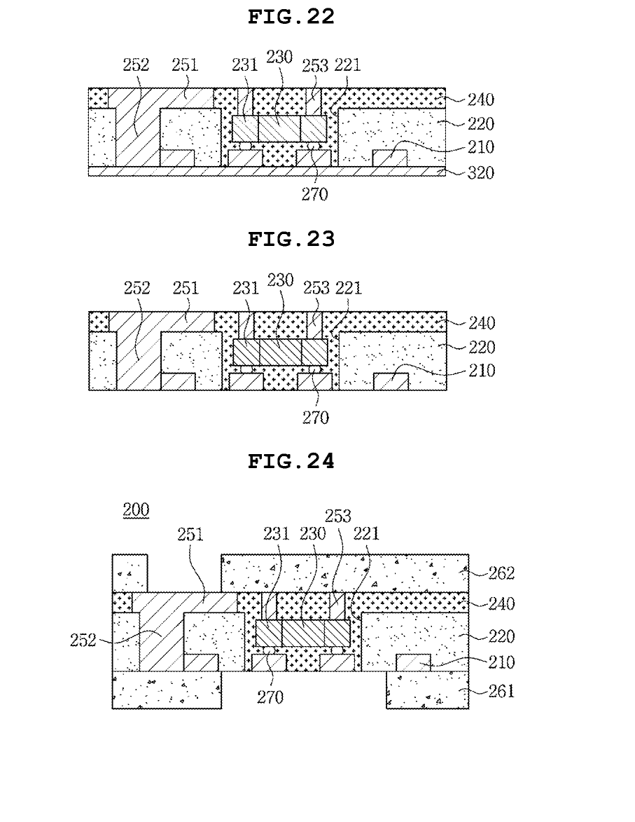

Referring to FIG. 22, the carrier insulating layer 310 (FIG. 21) may be removed.

According to the exemplary embodiment of the present disclosure, a carrier metal layer 320 may be separated from the carrier insulating layer 310 (FIG. 21). In this case, only the carrier insulating layer 310 (FIG. 21) is separated and the carrier metal layer 320 may remain under the first insulating layer 220, the first via 252, and the first circuit pattern 210.

Referring to FIG. 23, the carrier metal layer 320 (FIG. 22) may be removed.

According to the exemplary embodiment of the present disclosure, the carrier metal layer 320 (FIG. 22) is removed and thus the lower surface of the first insulating layer 220, the lower surface of the first via 252, and the lower surface of the first circuit pattern 210 may be exposed to the outside.

The exemplary embodiment of the present disclosure describes, by way of example, that when the carrier member 300 (FIG. 21) is removed, the carrier insulating layer 310 (FIG. 21) and the carrier metal layer 320 (FIG. 21) are removed separately. However, the method of removing the carrier member 300 (FIG. 21) is not limited thereto. The carrier member 300 (FIG. 21) may be removed by various methods according to the structure, the material, and the selection of those skilled in the art.

Referring to FIG. 24, the first solder resist layer 261 and the second solder resist layer 262 may be formed.

According to the exemplary embodiment of the present disclosure, the first solder resist layer 261 may be formed beneath the first insulating layer 220. Further, the first solder resist layer 261 is formed to enclose the lower surface of the first circuit pattern 210 and the lower surface of the first via 252 which are exposed from the first insulating layer 220. In this case, the first solder resist layer 261 may be formed to make a portion electrically connected to the outside in the first via 252 and the first circuit pattern 210 be exposed to the outside.

According to the exemplary embodiment of the present disclosure, the second solder resist layer 262 may be formed on the second insulating layer 240. The second solder resist layer 262 may be formed to surround the upper surface of the second circuit pattern 251 and the upper surface of the second via 253 which are exposed from the upper surface of the second insulating layer 240. In this case, the second solder resist layer 262 may be formed to make a portion electrically connected to the outside in the second circuit pattern 251 and the second via 253 be exposed to the outside. For example, the first solder resist layer 261 and the second solder resist layer 262 may be made of a heat resistant covering material.

According to the exemplary embodiment of the present disclosure, the first solder resist layer 261 and the second solder resist layer 262 may be made of the photosensitive material. When the first solder resist layer 261 and the second solder resist layer 262 are made of the photosensitive material, a difference in coefficient of thermal expansion (C 1′E) between the first insulating layer 220 and the second insulating layer 240 may be reduced. For example, the first solder resist layer 261, the second solder resist layer 262, the first insulating layer 220, and the second insulating layer 240 may have the same CTE. The so formed embedded board 200 is advantageous in warpage property prediction and therefore may be manufactured to improve the warpage or to be warped according to a customer's demand.

Although not illustrated in the exemplary embodiment of the present disclosure, the area exposed by the first solder resist layer 261 and the second solder resist layer 262 may be subjected to the surface treatment.

According to the exemplary embodiment of the present disclosure, even though the via land is omitted, the first via hole 242 may be processed. As described above, as the via land is omitted, the freedom of circuit design may be improved.

As set forth above, according to the embedded board and the method of manufacturing the same in accordance with the exemplary embodiments of the present disclosure, the signal transmission distance may be shortened and both sides of the electronic device may be connected to the circuit pattern to improve the electrical characteristics.

According to the embedded board and the method of manufacturing the same in accordance with the exemplary embodiments of the present disclosure, the thickness of the insulating layer may be controlled to control the entire thickness.

According to the embedded board and the method of manufacturing the same in accordance with the exemplary embodiments of the present disclosure, the via land may be omitted to increase the freedom of circuit design and implement the high-density circuit.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. An embedded board, comprising:
an insulating layer made of a photosensitive material;
a first circuit pattern formed inside the insulating layer and formed to make a lower surface be exposed from a lower surface of the insulating layer;
an electronic device disposed on the first circuit pattern;
a second circuit pattern formed on the insulating layer; and
a first via formed inside the insulating layer and having an upper surface connected to the second circuit pattern and formed to make a lower surface be exposed from the lower surface of the insulating layer.

2. The embedded substrate of claim 1, wherein the second circuit pattern is formed on the upper surface of the insulating layer and is thus formed to protrude from the insulating layer.

3. The embedded substrate of claim 1, wherein the second circuit pattern is formed inside the insulating layer and is formed to make an upper surface be exposed from the upper surface of the insulating layer.

4. The embedded substrate of claim 3, further comprising:
a second via formed inside the insulating layer, formed to make an upper surface be exposed from the upper surface of the insulating layer, and having a lower surface electrically connected to the electronic device.

5. The embedded substrate of claim 1, wherein the insulating layer includes:
a first insulating layer provided with the first circuit pattern; and
a second insulating layer provided with the second circuit pattern.

6. The embedded substrate of claim 5, wherein the first insulating layer has a thickness larger than a sum of thicknesses of the electronic device and the first circuit pattern.

7. The embedded substrate of claim 1, wherein the electronic device is electrically connected to the first circuit pattern.

8. The embedded substrate of claim 1, further comprising:
a solder resist layer formed on at least one of the upper and lower portions of the insulating layer.

9. The embedded substrate of claim 8, wherein the solder resist layer is made of the photosensitive material.

10. The embedded substrate of claim 1, wherein the first via is electrically connected to a side of the first circuit pattern.

11. A method of manufacturing an embedded board, comprising:
preparing a carrier member provided with a first circuit pattern;
forming a first insulating layer made of a photosensitive material in the carrier member so as to have the first circuit pattern embedded therein;
forming a cavity through which the first circuit pattern is exposed by exposing and developing the first insulating layer;
disposing an electronic device in the first circuit pattern exposed through the cavity;
forming a second insulating layer made of the photosensitive material on the first insulating layer and inside the cavity; and
forming a second circuit pattern in a first via penetrating through the first insulating layer and the second insulating layer.

12. The method of claim 11, further comprising:
after the forming of the second circuit pattern, removing the carrier member.

13. The method of claim 11, further comprising:
after the disposing of the electronic device, performing a reflow by interposing a soldier between the electronic device and the first circuit pattern.

14. The method of claim 11, wherein the forming of the first via and the second circuit pattern includes:
forming a first via hole penetrating through the first insulating layer and the second insulating layer by performing exposure and development; and
forming the first via and the second circuit pattern by performing plating on the first via hole and the second insulating layer.

15. The method of claim 11, wherein the forming of the first via and the second circuit pattern includes:
forming a second via formed in the first insulating layer and the second insulating layer so as to be electrically connected to the electronic device.

16. The method of claim 15, wherein the forming of the first via, the second circuit pattern, and the second via includes:
forming a first via hole penetrating through the first insulating layer by performing exposure and development;
forming an opening in the second insulating layer by performing exposure and development and forming a second via hole through which an upper surface of the electronic device is exposed; and
forming the first via, the second circuit pattern, and the second via by performing the plating on the first via hole, the opening, and the second via hole.

17. The method of claim 12, further comprising:
after the removing of the carrier member, forming a solder resist layer beneath the first insulating layer and on the second insulating layer.

18. The method of claim 11, wherein in the forming of the first insulating layer, the first insulating layer has a thickness larger than a sum of thicknesses of the electronic device and the first circuit pattern.

19. The method of claim 11, wherein the forming of the cavity includes forming an internal via hole by exposing and developing the first insulating layer.

20. The method of claim 19, wherein in the forming of the second insulating layer, the second insulating layer is filled inside the internal via hole.

21. The method of claim 20, wherein in the forming of the first via and the second circuit pattern, the first via is formed in the internal via hole filled with the second insulating layer.

22. The method of claim 11, wherein in the forming of the first via and the second circuit pattern, the first via is electrically connected to a side of the second circuit pattern.

23. The method of claim 17, wherein in the forming of the solder resist layer, the solder resist layer is made of the photosensitive material.
